(19) United States
(12) Patent Application Publication
(10) Pub. No.: US 2026/0190377 A1
(43) Pub. Date: Jul. 2, 2026

(54) SELECTIVE AREA TEMPLATE FOR TWO-DIMENSIONAL EPITAXIAL CHANNEL GROWTH ON LARGE WAFERS WITH FUNCTIONALIZED PATTERNED AREAS

(71) Applicant: Intel Corporation, Santa Clara, CA (US)

(72) Inventors: Nazmul Arefin, Beaverton, OR (US); Kirby Maxey, Hillsboro, OR (US); Mahmut Sami Kavrik, Hillsboro, OR (US); Carl H. Naylor, Portland, OR (US); Scott Semproni, Fair Lawn, NJ (US); Azimkhan Kozhakhmetov, Portland, OR (US); Kevin P. O’Brien, Portland, OR (US); Matthew Metz, Portland, OR (US); Uygar Avci, Portland, OR (US)

(73) Assignee: Intel Corporation, Santa Clara, CA (US)

(21) Appl. No.: 19/002,266

(22) Filed: Dec. 26, 2024

(51) Int. Cl. H10D 30/47; H01L 21/02; H01L 21/3205; H10D 30/00; H10D 30/01; H10D 62/80; H10D 64/66; H10D 64/68

(52) U.S. Cl. CPC H10D 30/481; H10D 30/017; H10D 30/0191; H10D 30/502; H10D 62/883; H10D 64/667; H10D 64/691; H10P 14/412; H10P 14/6349; H10P 14/6546; H10P 14/69391; H10P 14/69392

(57) ABSTRACT

Integrated circuit (IC) devices having transistors with two-dimensional channel layers, such as TMD (transition metal dichalcogenide) nanoribbon channels in gate-all-around (GAA) FETs (field-effect transistors). An IC device may include a stack of nanoribbon channel layers through a gate structure having interface layers between the channel layers and the gate dielectric layers. The interface layers may include an element not present in the gate dielectric layers or the channel layers. A channel layer may be on an underlying interface layer, between the channel layer and the underlying gate dielectric layer, but the gate dielectric layer over the channel layer may be directly on the channel layer. The material stack of gate and channel material layers may be over an electrically insulating layer that serves as an epitaxial growth template for the subsequently formed crystalline layers. A sacrificial mask layer may confine epitaxial growth to single-nucleation areas.

### BACKGROUND

As transistor dimensions in integrated circuit (IC) devices are continually scaled down, novel and innovative materials gain importance. For example, two-dimensional (2D) materials, such as TMDs (transition metal dichalcogenides) are increasingly examined because of their potentially valuable properties. However, the growth (or exfoliation and transfer) of high-quality (e.g., monocrystalline) channel structures over an entire (for example, of production size, e.g., of 300 mm) wafer remains challenging.

New materials, techniques, and structures are needed to improve transistor in IC devices and their manufacture.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate plan and cross-sectional profile views of an integrated circuit (IC) device and transistor structure having a stack of nanoribbon channel layers extending through a gate stack between source and drain terminals, in accordance with some embodiments;

FIG. 2 is a flow chart of methods for forming transistors having stacks of two-dimensional (2D) channel layers, in accordance with some embodiments;

FIGS. 3A, 3B, 3C, 3D, 3E, 3F, 3G, and 3H illustrate plan and cross-sectional views of an IC device with transistor structures having stacks of 2D channel layers, at various stages of manufacture, in accordance with some embodiments;

FIG. 4 illustrates a diagram of an example data server machine employing an IC device having monocrystalline 2D channel layers and interface layers between the channel layers and underlying gate dielectrics; and

FIG. 5 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve integrated circuit (IC) devices having transistors with nanoribbon channels, including nanoribbons of two-dimensional (2D) materials, such as TMDs (transition metal dichalcogenides).

Nanoribbon channels of 2D materials may provide nonplanar transistors (such as gate-all-around (GAA) field-effect transistors (FETs)) with superior electrical characteristics, e.g., relative to silicon nanoribbons. For example, the thinness of 2D nanoribbons may be necessary to maintain satisfactory subthreshold swing at shortened gate lengths. These thinner nanoribbon channels also enable the stacking of more electrically parallel channel structures in a nanoribbon stack having the same height.

Metal-oxide-semiconductor (MOS) FETs may have nanoribbon channels, e.g., TMD nanoribbons, with interface layers between the nanoribbons and corresponding gate dielectric layers. The interface layer may direct growth of the nanoribbon channel, for example, along only a single axis (rather than in both lateral dimensions) and to desired dimensions. In many embodiments, the interface layer is between a nanoribbon and an underlying gate dielectric, but not over the nanoribbon, between the nanoribbon and an overlying gate dielectric. In some embodiments, the interface layers are thin (e.g. mono)layers of an element on (or incorporated into) the underlying gate dielectric layers.

An array of the channel layers may be epitaxially grown simultaneously across a wafer, but with each channel grown separately in a confined growth area, which may ensure controlled nucleation and subsequent monocrystalline growth. A mask layer may be patterned to include openings that confine the growth. A selective growth material may be deposited before the channel material to serve as a growth template for the epitaxial deposition of the channel material (e.g., with the mask layer over the template layer and the confined growth areas of the template layer exposed and available in the mask openings).

Material layers in a layer stack (for example, of gate electrode and gate insulator materials) may be of crystalline materials that enable the controlled (e.g., monocrystalline) epitaxial growth of each subsequent layer. The layer stack may include a stack of channel layers interleaved with gate stack layers, the channel layers extending through the gate stack. Gate insulator layers may be functionalized (and the interface layers may be formed on the gate insulator layers) to direct the growth of the channel layers on the gate insulator layers.

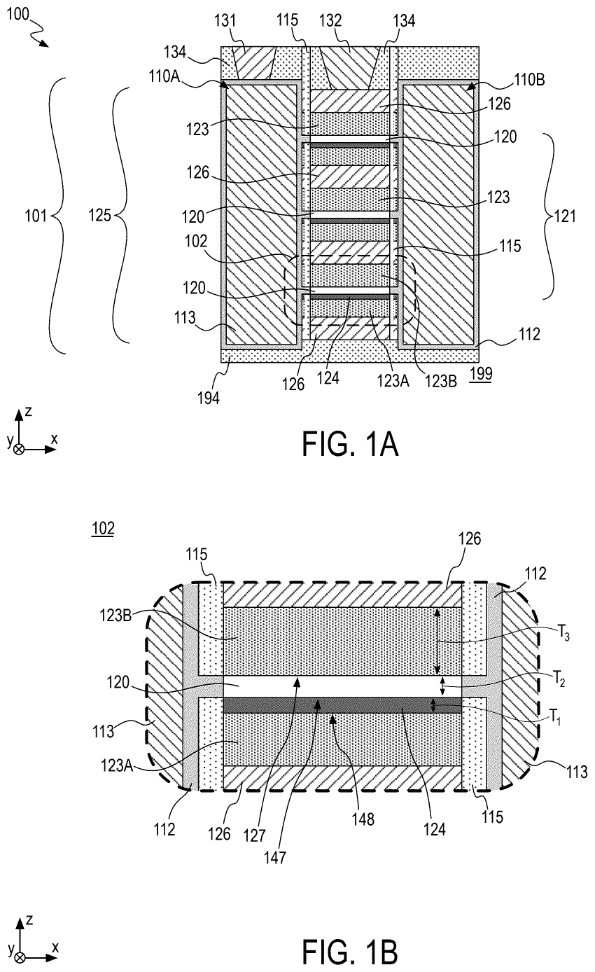

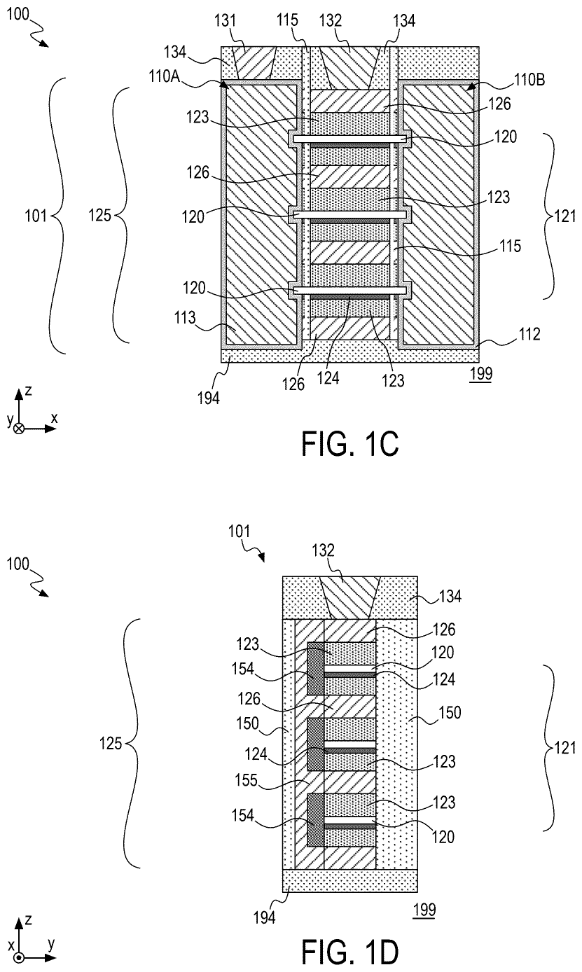

FIGS. 1A, 1B, 1C, and 1D illustrate plan and cross-sectional profile views of an IC device 100 and transistor structure 101 having a stack 121 of nanoribbon channel layers 120 extending through a gate stack 125 between source and drain terminals 110, in accordance with some embodiments. View 102 of FIG. 1A is shown at greater magnification in FIG. 1B. Nanoribbon layers 120 may each be a crystalline monolayer of a TMD, a notable class of 2D materials. Transistor structure 101 and gate stack 125 include gate dielectric layers 123 between nanoribbon layers 120 and a gate electrode 126. Channel layers 120 are over interface layers 124, which are between each of nanoribbons layers 120 and insulator material layers 123. Transistor structure 101 may be formed by any suitable means. In many embodiments, gate electrode 126 and dielectric and interface layers 123, 124 in gate stack 125 and channel layers 120 are all epitaxially grown over substrate 199. Advantageously, the materials of layers 120, 123, 124, 194 and gate electrode 126 enable the epitaxial growth of subsequent layers in stacks 121, 125 (e.g., layers 120, etc.) in transistor structure 101.

FIG. 1A shows IC apparatus or device 100 having transistor structure 101 in or on substrate 199. Transistor structure 101 includes first and second terminals 110A, 110B and stack 121 of channel material layers 120 between terminals 110. Transistor structure 101 includes gate stack 125 between terminals 110A, 110B. Layers 120 extend through gate stack 125 and between terminals 110. Gate stack 125 includes gate electrode 126 between nanoribbon layers 120 and insulator layers 123 between layers 120 and electrode 126. Gate stack 125 also includes interface layers 124 between each of nanoribbons layers 120 and a corresponding insulator layer 123. In many embodiments, interface layers 124 are thin layers 124 (e.g., monolayers 124) over insulator layers 123A (e.g., between layers 120, 123A), but not over layers 120 (e.g., between layers 120, 123B). In some such embodiments, interface layers 124 over insulator layers 123A promote advantageous (e.g., directed) growth of nanoribbon layers 120.

In many embodiments, transistor structure 101 is symmetric (e.g., in the x-dimension), and source and drain terminals 110A, 110B are identical. For example, the labels for terminals 110 of transistor structure 101 may be determined solely by the electrical connections of source and drain terminals 110A, 110B (e.g., to a positive or negative power supply).

In the exemplary embodiment of FIG. 1A, channel material layers 120 are TMD nanoribbon layers 120, but other embodiments may employ other materials. The channel material of layers 120 may be any suitable material (e.g., a 2D material), and nanoribbon layers 120 may be of any suitable width(s) (e.g., in the y-dimension). For example, in some embodiments, nanoribbon layers 120 have narrow widths (e.g., approximately equal to a height of layer 120) and may be considered nanowire layers 120. In some embodiments, nanoribbon layers 120 are sufficiently wide to be considered nanosheet layers 120. In many embodiments, channel material layers 120 have a thickness (e.g., in the z-dimension) of less than 1 nm.

In the exemplary embodiment of FIG. 1A, each of nanoribbon layers 120 are TMD layers 120 and include a metal and a chalcogen, e.g., in a crystalline lattice structure. In many embodiments, each of TMD layers 120 are 2D layers 120, for example, each a single molecular monolayer. In many embodiments, the metal and chalcogen are in a 2H phase, which may correspond to the TMD having semiconducting properties. In some embodiments, the metal is in a first atomic plane between second and third atomic planes of the chalcogen, for example, in a 2H phase (hexagonal crystal system). In some embodiments, the metal is tungsten or molybdenum, and the chalcogen is sulfur or selenium. Channel layers 120 are vertically aligned in stack 121, which may include any suitable number of layers 120. In many embodiments, due to a smaller thickness of 2D layers 120, stack 121 includes more layers 120 (for example, six or more) than is typical for a GAA FET. The smaller thickness of 2D layers 120 may provide superior electrical performance for transistor structure 101, for example, by enabling the deployment of more electrically parallel channel layers 120.

Nanoribbon layers 120 extend through gate stack 125 between terminals 110. Gate stack 125 includes an electrode material (e.g., in gate electrode 126) between layers 120 and an insulator material (e.g., a gate dielectric in insulator layers 123) between nanoribbon layers 120 and the electrode material. Gate insulator layer 123 electrically insulates gate electrode 126 from channel layers 120 and allows for electrostatic control by gate electrode 126 of channel layers 120. Gate electrode 126 may be of any suitably conductive material(s), such as one or metals, etc., and insulator layers 123 may be of any suitably insulating material(s), such as one or dielectrics, etc. In many embodiments, the insulator material of layers 123 advantageously enables the epitaxial growth of nanoribbon (etc.) layers 120 and/or gate electrode 126. In many embodiments, the electrode material of gate electrode 126 advantageously enables the epitaxial growth of gate insulator layers 123. For example, the materials of layers 123 and electrode 126 may serve as growth templates for the epitaxial depositing of subsequently formed layers.

Gate electrode 126 is on gate insulator layer 123 (e.g., layer 123B) and may include one or more of p-type or n-type work function metals, depending on whether the transistor is a PMOS or an NMOS transistor. Gate electrode 126 advantageously includes an electrode material that serves as a template for epitaxial growth of crystalline insulator layer 123 (e.g., layer 123A). In some embodiments, the material of electrode 126 is a metal (e.g., different than a metal of layers 120), such as titanium. In some embodiments, the material of electrode 126 includes nitrogen, e.g., in a metal nitride, such as titanium nitride. In some such embodiments, the material of electrode 126 has a crystalline structure. In some embodiments, gate electrode 126 includes two or more metal layers, where one or more metal layers are work function metal layers (e.g., adjacent channel layers 120) and at least one metal layer is a fill metal layer. For a PMOS transistor, metals that may be used for the gate electrode include, but are not limited to, ruthenium, palladium, platinum, cobalt, nickel, and conductive metal oxides, e.g., ruthenium oxide. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, or tantalum carbide.

Channel layers 120 extend through electrode 126 with gate insulator layer(s) 123 between layers 120 and electrode 126. Insulator layer 123 advantageously includes a high-permittivity (“high-k”) dielectric material, which may provide superior electrostatic control while minimizing gate leakage currents. Advantageously, gate insulator layers 123 are of an insulator material with a crystalline structure that provides a template for the epitaxial growth of 2D layers 120, such as a crystalline metal oxide. In some embodiments, the insulator material of layer 123 includes oxygen and hafnium (e.g., in hafnium oxide). In some embodiments, the insulator material of layer 123 includes oxygen and aluminum (e.g., in aluminum oxide). Layer 123 may have one or more sublayers. The insulator material of layers 123 may be any suitable material(s), including one or more of hafnium oxide, hafnium silicon oxide, lanthanum oxide, lanthanum aluminum oxide, zirconium oxide, zirconium silicon oxide, tantalum oxide, titanium oxide, barium titanium oxide, strontium titanium oxide, yttrium oxide, aluminum oxide, etc. Other dielectric material may be used, such as a silicon oxide (e.g., silicon dioxide, SiO₂).

Gate stack 125 may include the insulator (e.g., dielectric) material in first and second layers 123A, 123B under and over layers 120, respectively. Gate insulator layers 123B are on channel layers 120. Channel layers 120 are over gate insulator layers 123A, with each of layers 120 on an interface layer 124 between a corresponding insulator layer 123A and the channel layer 120. Stacks 125, 121 are interleaved with layers 123A, 123B, 124 interleaved between layers 120: Interface layers 124 are on first layers 123A, channel material layers 120 are on interface layers 124, and second layers 123B are on channel material layers 120.

Interface layers 124 are between each of nanoribbon layers 120 and a corresponding insulator layer 123A. Interface layers 124 are on (or incorporated in) the corresponding insulator layer 123A. Interface layers 124 include a material (e.g., an element) not substantially present in layers 120 and/or layers 123 (e.g., only present at a concentration of less than 1% of a total composition of layer 123). Interface layers 124 may have a very small thickness, e.g., of less than 0.5 nm. For example, an interface layer 124 may be a monolayer of atoms or molecules (e.g., of an element or elements not present in layers 120, 123) over and in contact with insulator layer 123A, and a channel layer 120 may be over and in contact with the interface layer 124. A monolayer of atoms or molecules is less than two atoms or molecules thick, but does not necessarily indicate that a layer 124 is continuous over layer 123A or between layers 120, 123A. The atoms of a monolayer 124 may be interspersed on (and, e.g., bonded with) the uppermost atoms of insulator layer 123A below.

Interface layer 124 may be between layers 120, 123 without completely separating layers 120, 123. For example, layer 124 may be atoms of the element (e.g., phosphorus) bonded with one or more atoms of an insulator layer 123A below and, in some embodiments, incorporated into the structure of layer 123A. In different embodiments, the atoms of the element in layer 124 may be present in different quantities (e.g., with different ratios of atoms of the element in layer 124 to atoms of layer 123A), for example, covering the insulator layer 123A below more or less thoroughly. Layers 123, 124 may provide growth templates for other layers in stacks 121, 125 (e.g., channel layers 120), and layers 124 (and the element in layers 124) may direct growth of subsequently formed layers in a desired manner. For example, in some embodiments, a higher quantity of atoms of the element (e.g., phosphorus) in layer 124 more thoroughly covers the insulator layer 123A below and a wider growth of the subsequently formed channel layer 120 is directed, while in other embodiments, a lower quantity of atoms of the element (e.g., phosphorus) in layer 124 less thoroughly covers the insulator layer 123A below and a narrower growth of the subsequently formed channel layer 120 is directed.

The element in layer 124 may not be needed at any depth below the interface between layers 120, 123A, and no atoms (or only very low concentrations) of the element in layer 124 are present in layers 123A (e.g., below a pure monolayer of the element, or about 0.5 nm under layers 120). In some embodiments, a thin interface layer 124 (e.g., a monolayer) of an element (e.g., phosphorus) is on an insulator layer 123A, between the insulator layer 123A and a corresponding channel layer 120, and the element is not present in layers 120, 123A. In other embodiments, a thin interface layer 124 (e.g., a monolayer) of an element (e.g., phosphorus) is on an insulator layer 123A, between the insulator layer 123A and a corresponding channel layer 120, and the element is not substantially present in layers 120, 123A. In some such embodiments, the element not substantially present in layers 120, 123A is present in layer 123A at a concentration of less than 1%. In some such embodiments, the element not substantially present in layers 120, 123A is present in layer 123A at a concentration of less than 0.1%.

Layers 120, 123, 124, 194 and gate electrode 126 may all have crystalline structures (e.g., epitaxially grown, one over the other) of various materials. Transistor structure 101 includes repeating portions in interleaved stacks 121, 125: channel material layers 120 extend through gate electrode 126, and insulator layers 123 are between layers 120 and electrode 126. In some embodiments, a TMD nanoribbon layer 120 has a first crystalline structure with a first metal in a first atomic plane between second and third atomic planes of a chalcogen. In some such embodiments, an insulator layer 123A under the TMD nanoribbon layer 120 includes insulator material in a second crystalline structure of oxygen and a second metal (e.g., different than the first metal). In some such embodiments, an insulator layer 123B over the TMD nanoribbon layer 120 includes the same insulator material of layer 123A in the same second crystalline structure of oxygen and the second metal. In some such embodiments, the electrode material of gate electrode 126 includes a third metal in a third crystalline structure under the lower insulator layer 123A and over the upper insulator layer 123B.

Gate stack 125 (including electrode 126) is in transistor structure 101 and between source and drain terminals 110 of structure 101. Spacers 115 provide electrical isolation, e.g., between gate electrode 126 and source and drain terminals 110. Spacer 115 may be of a low-permittivity (“low-k”) dielectric material.

Channel material layers 120 in stack 121 extend through gate stack 125 and between source and drain terminals 110 over insulator layer 194 of substrate 199. Terminals 110 are electrically conductive structures between and coupled by semiconductor layers 120. Terminals 110 may include one or more metals, for example, in one or more layers. In the exemplary embodiment of FIG. 1A, terminals 110 include liner and bulk materials 112, 113. Liner material 112 makes up the sidewalls of source and drain terminals 110. Liner material 112, as in FIG. 1A, may be conformal to spacers 115 and multiple ends of multiple layers 120. In some embodiments (as shown at FIG. 1C), layers 120 extend into terminals 110, laterally beyond spacers 115 and the outermost sidewalls of source and drain terminals 110, and liner material 112 is conformal to the ends of layers 120 that extend into the extent of source and drain terminals 110, as well as the upper and lower surfaces of layers 120.

Liner material 112 may be any suitable material(s), e.g., sufficiently conductive and capable of conforming to adjoining structures. Some liner materials 112 may have a propensity for forming bonds with the 2D materials of layers 120, e.g., TMD. Liner material 112 may include a metal. In some embodiments, liner material 112 includes at least one of antimony, gold, silver, nickel, titanium, ruthenium, tin, bismuth, aluminum, germanium, tantalum, palladium, platinum, iridium, tungsten, rhodium, or molybdenum. Some materials 112 may be advantageously deployed in a given transistor type, e.g., N- or P-type. For example, in some N-type embodiments, liner material 112 includes at least one of antimony, gold, silver, nickel, titanium, ruthenium, tin, bismuth, aluminum, germanium, or tantalum. In some P-type embodiments, liner material 112 includes at least one of palladium, platinum, ruthenium, gold, iridium, tungsten, nickel, rhodium, or molybdenum. Liner material 112 may be a compound, 2D or otherwise, of a metal and a chalcogen. In some embodiments, liner material 112 includes one of rhenium, cobalt, or nickel, and one of sulfur or selenium (e.g., ReₓS_{y}, ReₓSe_{y}, CoₓS_{y}, CoₓSe_{y}, NiₓS_{y}, or NiₓSe_{y}).

Liner material 112 may be a 2D material, which may provide a conductive surface of source or drain terminals 110 while minimizing a thickness of liner material 112. In some embodiments, liner material 112 includes graphene or a TMD. The TMD may include both, one of, or neither of a transition metal and a chalcogen of a TMD nanoribbon layer 120. In some embodiments, the TMD of liner material 112 includes a dopant, e.g., to increase conductivity. TMD of the same or similar composition may have differing electrical characteristics due to having differing crystalline structures. For example, a TMD in a 2H crystalline phase (e.g., a molecular monolayer with vertically aligned chalcogen atoms) may be a semiconductor, while a TMD with the same composition but in a 1T crystalline phase (e.g., a molecular monolayer with vertically unaligned chalcogen atoms) may be metallic (or semimetallic). In some embodiments, the TMD of liner material 112 is in a metallic crystalline phase. In some embodiments, the TMD of liner material 112 is in a 1T crystalline phase. Other materials may be used. Some liner materials 112 include a TMD monolayer having two chalcogen atoms for every metal atom, but with a different chalcogen above than below the metal atoms. In some embodiments, an atomic plane of a metal is between an atomic plane of sulfur and an atomic plane of selenium (e.g., a molecular monolayer of MoSSe or WSSe).

Liner material 112 encloses bulk material 113 of source and drain terminals 110. Bulk material 113 may be or include one or more metals of sufficient conductivity, e.g., copper, tungsten, cobalt, or ruthenium. Other materials may be suitable. These or other bulk materials 113 may be selected for their compatibility with a given material 112 and suitability for metallization embodiments.

Contact vias 131 through isolation material 134 couple source and drain terminals 110 to an interconnect network (not shown), for example, over transistor structure 101 and terminals 110. Gate via 132 through isolation material 134 couples electrode 126 to an interconnect network (not shown), for example, over transistor structure 101 and electrode 126. Isolation material 134 over terminals 110 may be the same or different isolation material 134 as over electrode 126. Material 134 may be any suitable material, such as a low-k dielectric material, that electrically insulates adjacent structures.

Isolation layer 194 under terminals 110 and stacks 121, 125 may be of or include the same or different isolation material as material(s) 134 over electrode 126 and terminals 110. Isolation layer 194 under terminals 110 and stacks 121, 125 may be of or include the same or different isolation material as layers 123 under channel layers 120. Layer 194 may be of any suitable material, such as a dielectric material, that electrically insulates adjacent structures, such as terminals 110 and electrode 126 from each other and other portions of substrate 199. In many embodiments, the material of layer 194 serves as a growth template for the epitaxial depositing of subsequently formed layers. For example, the isolation material of layer 194 may advantageously enable the epitaxial growth of gate electrode 126.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials. In many embodiments, substrate 199 includes a semiconductor material under layer 194.

FIG. 1B illustrates view 102 from FIG. 1A in greater detail, including portions of stacks 121, 125 of transistor structure 101. The shown stack portion may be repeated (e.g., vertically, over and/or under the stack portion shown), as is shown in FIG. 1A. For example, channel layers 120, one over the other, may repeatedly extend through gate electrode 126, and electrode 126 may be both over and under layers 120, with insulator layers 123 over and under layers 120, between layers 120 and electrode 126. Interface layer 124 is between channel layer 120 and an insulator layer 123A under channel layer 120.

The materials of layers 120, 123, 124 and electrode 126 are in direct contact with the materials above and below. The insulator material of insulator layer 123B is on upper surface 127 of nanoribbon layer 120. Nanoribbon layer 120 is on upper surface 147 of interface layer 124. A lower surface 148 of interface layer 124 is on the insulator material of insulator layer 123A.

Layers 120, 123, 124 and gate electrode 126 may all have crystalline structures (e.g., epitaxially grown, one over the other) of various materials. In some embodiments, channel layer 120 has a first crystalline structure with a first metal in a first atomic plane between second and third atomic planes of a chalcogen, e.g., in a TMD. In some such embodiments, layer 123A under layer 120 includes insulator material in a crystalline structure of oxygen and a second metal (e.g., different than the metal in layer 120). In some such embodiments, insulator layer 123B over layer 120 includes the same insulator material of layer 123A in the same crystalline structure of oxygen and the second metal. In some such embodiments, the electrode material of electrode 126 includes a third distinct metal in a third crystalline structure under layer 123A and over layer 123B. Interface layer 124 may include atoms incorporated into the crystalline structure of layer 123A and may direct the crystalline growth of channel layer 120.

Interface layer 124 is over and in contact (e.g., incorporated) with insulator layer 123A (e.g., at surface 148). Channel layer 120 is over and in contact with layer 124 (e.g., at surface 147). Interface layer 124 may be a monolayer of atoms (e.g., of phosphorus, etc.) or molecules not present in layers 120, 123. The atoms of a monolayer 124 may be intermingled with the atoms on an upper surface of insulator layer 123A below. Layer 124 may have a minimal thickness T₁ between layers 120, 123A, for example, of 0.5 nm or less. Layer 124 may have any suitable thickness T₁.

Nanoribbon layers 120 may be 2D layers 120 with a thickness T₂ of about 1 nm or less. For example, 2D layers 120 may be molecular monolayers 124 of TMD, e.g., with a crystalline lattice structure having a metal (such as molybdenum or tungsten) in a first atomic plane between second and third atomic planes of a chalcogen (such as sulfur or selenium). In many embodiments, layers 120 have a thickness T₂ of approximately 0.6 nm or less. As described, a small thickness T₂ of layers 120 may enable the deployment of more electrically parallel channel layers 120. Layer 120 may have any suitable thickness T₂.

Gate insulator layers 123 may have any suitable thickness T₃, for example, of 1 nm or more. Gate insulator layers 123A, 123B may be similar (e.g., the same with respect to layer 120 between layers 123A, 123B), except for the surface functionalization of layer 123A (e.g., interface layer 124 on layer 123A). For example, layers 123A, 123B may have the same thicknesses T₃ and compositions. In many embodiments, insulator layers 123A, 123B have different thicknesses T₃, e.g., with layer 123A having a thickness T₃ less than a thickness T₃ of layer 123B by thickness T₁ of layer 124. Advantageously, layer 123 includes a high-k dielectric material, which may allow for sufficient thickness T₃ (e.g., to minimize gate leakage currents) while providing satisfactory electrostatic control of channel layers 120.

FIG. 1C shows an embodiment of IC device 100 with transistor structure 101 having channel layers 120 of stack 121 extend into terminals 110, laterally beyond spacers 115 and the outermost sidewalls of source and drain terminals 110. For example, layers 123, 124 and electrode 126 are recessed with a length shorter than a channel length of layers 120, and upper and lower surfaces of layers 120 are exposed at the ends of layers 120. Liner material 112 is conformally over the ends of layers 120 that extend into the extent of source and drain terminals 110, as well as conformally over the upper and lower surfaces of layers 120.

FIG. 1D illustrates a cross-sectional profile view of transistor structure 101 in device 100 with a y-z viewing plane through gate stack 125 and between the source and drain terminals (not shown, e.g., in front of and behind the y-z viewing plane). Gate electrode 126 includes vertical portion 155, which couples the layer portions of electrode 126 in gate stack 125. Gate insulators 154 provide electrical isolation, e.g., between electrode 126 portion 155 and channel layers 120. Isolations 150 provide electrical isolation, e.g., to both sides of stacks 121, 125, between transistor structure 101 and adjacent structures. Isolations 150 are advantageously of a low-k dielectric material.

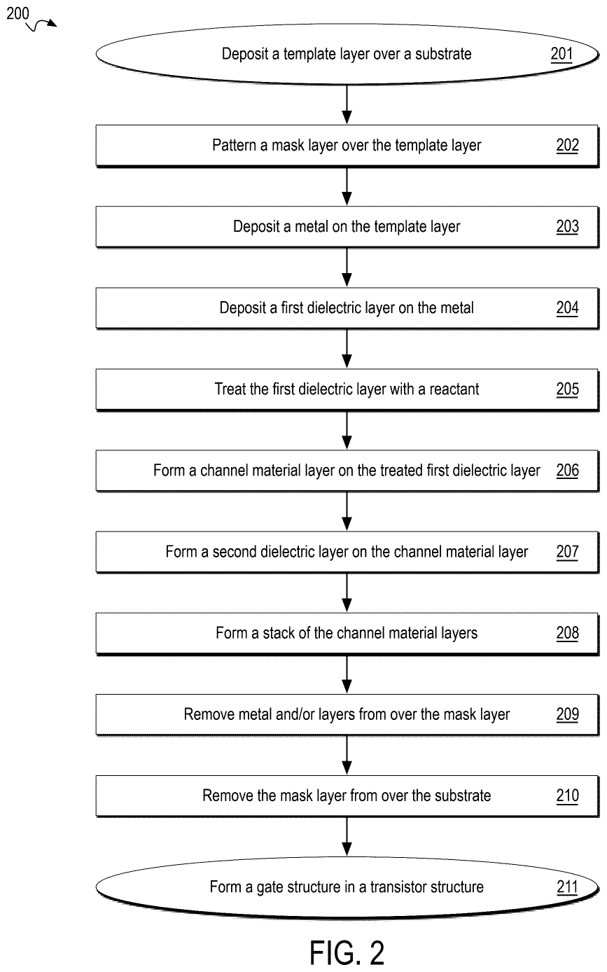

FIG. 2 is a flow chart of methods 200 for forming transistors having stacks of 2D channel layers, in accordance with some embodiments. Methods 200 include operations 201-211. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, the various layers may be deposited multiple times (e.g., in repeated portions) in a layer stack before removing a mask layer from over the substrate. Similarly, one or more various layers may be removed from over the mask layer (e.g., at operation 209) before other layers are deposited or otherwise formed. Some operations may be included within other operations so that the number of operations illustrated FIG. 2 is not a limitation of the methods 200.

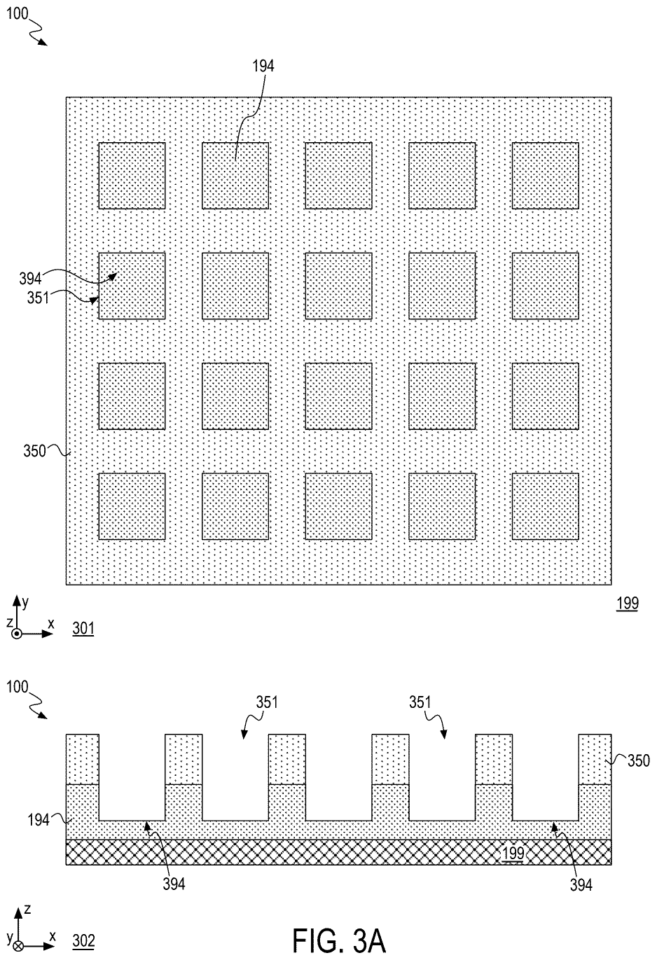

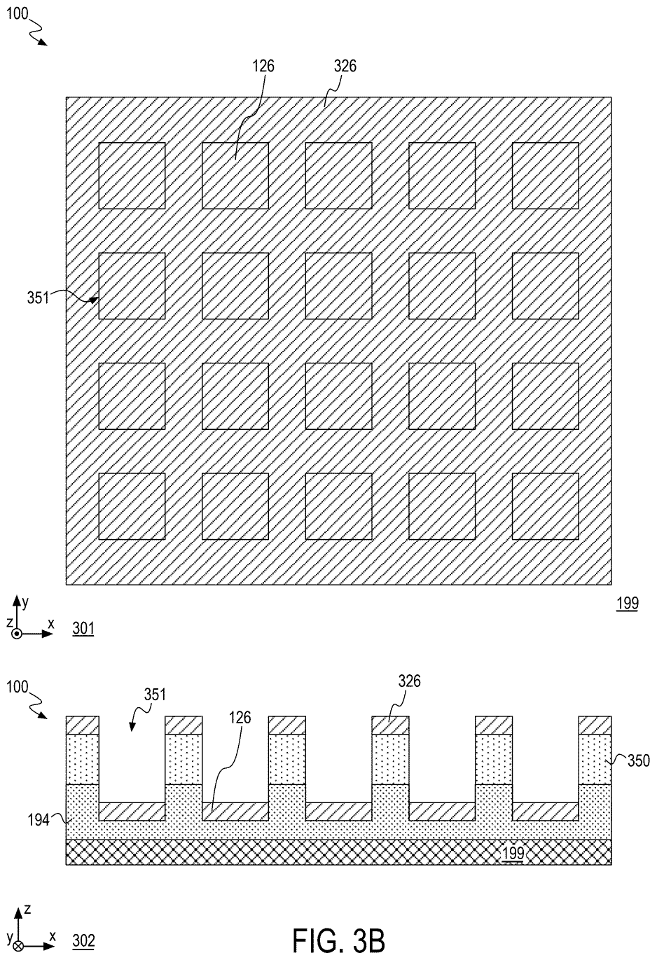

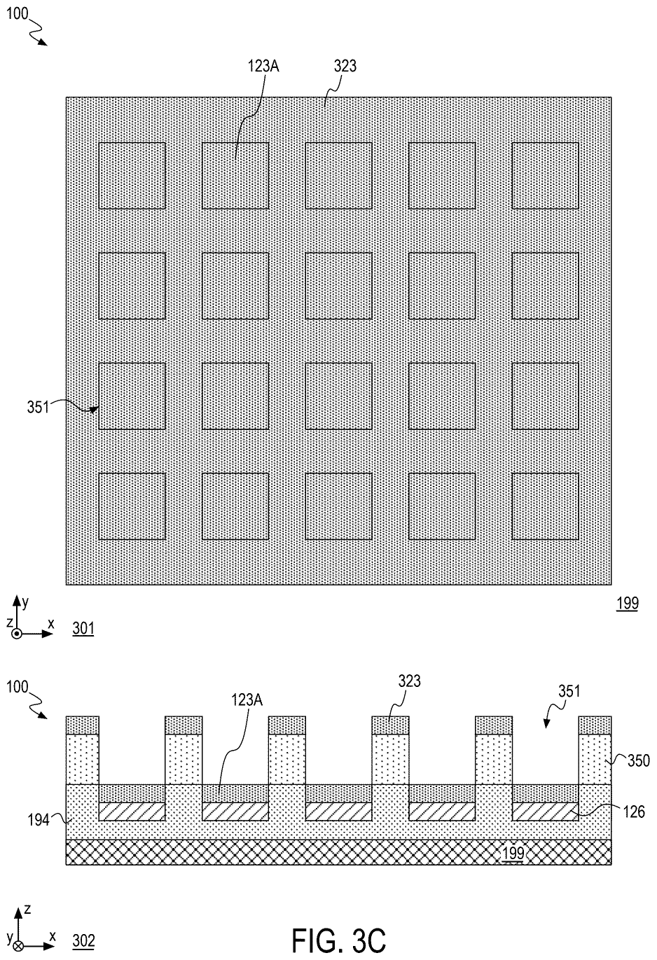

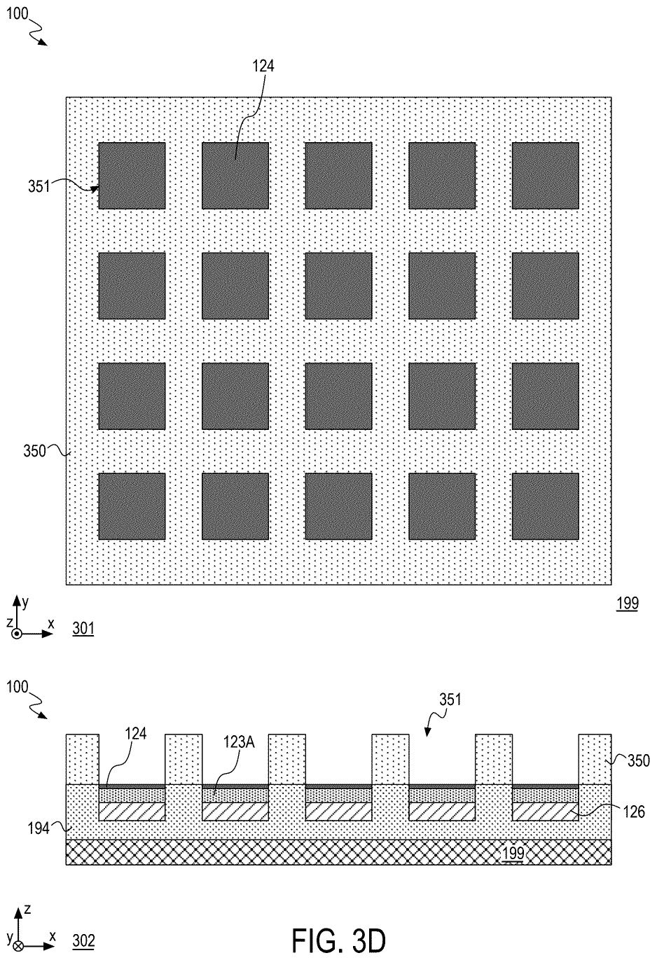

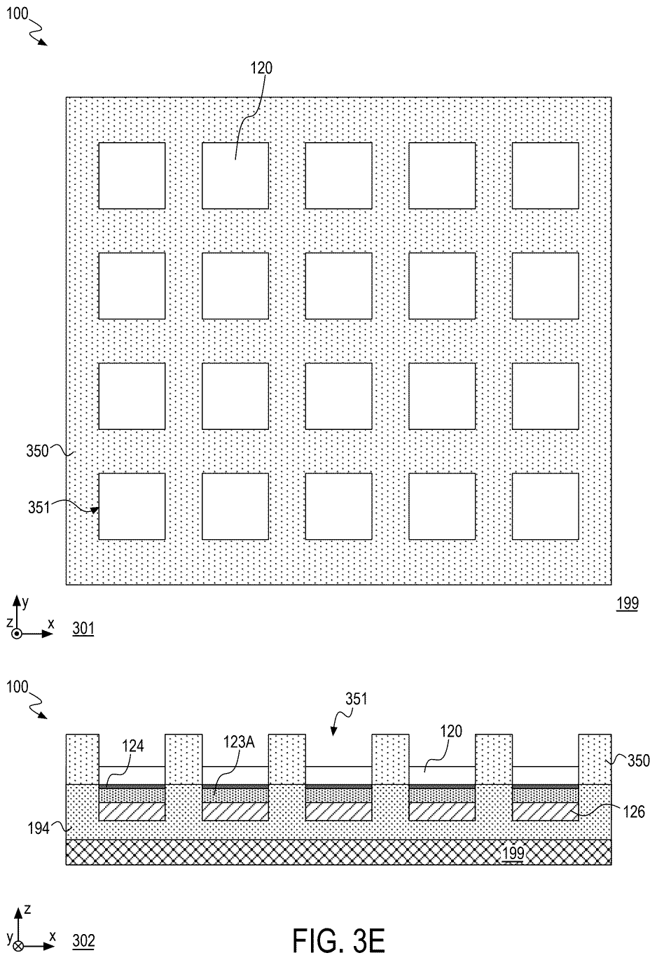

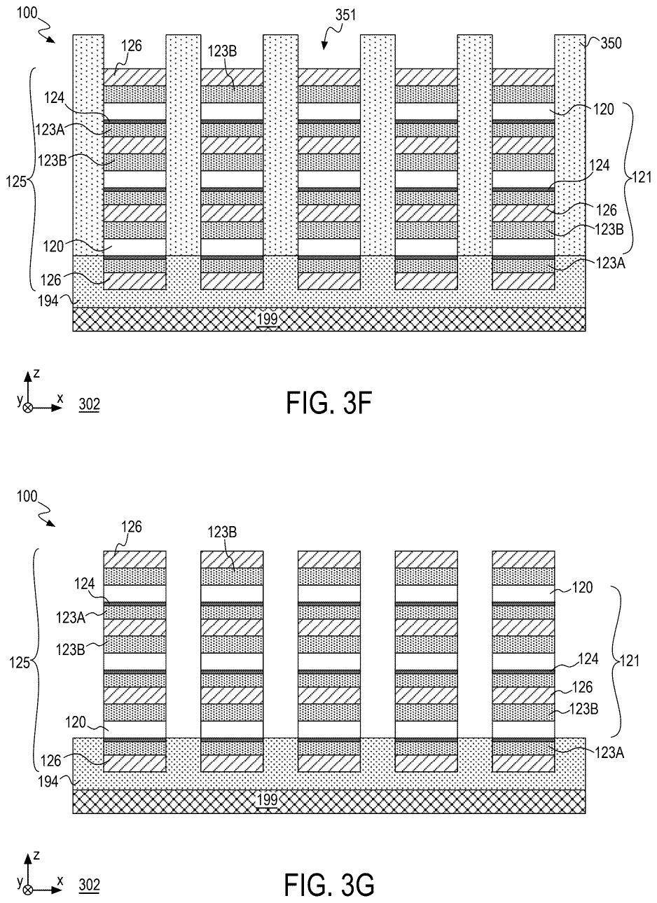

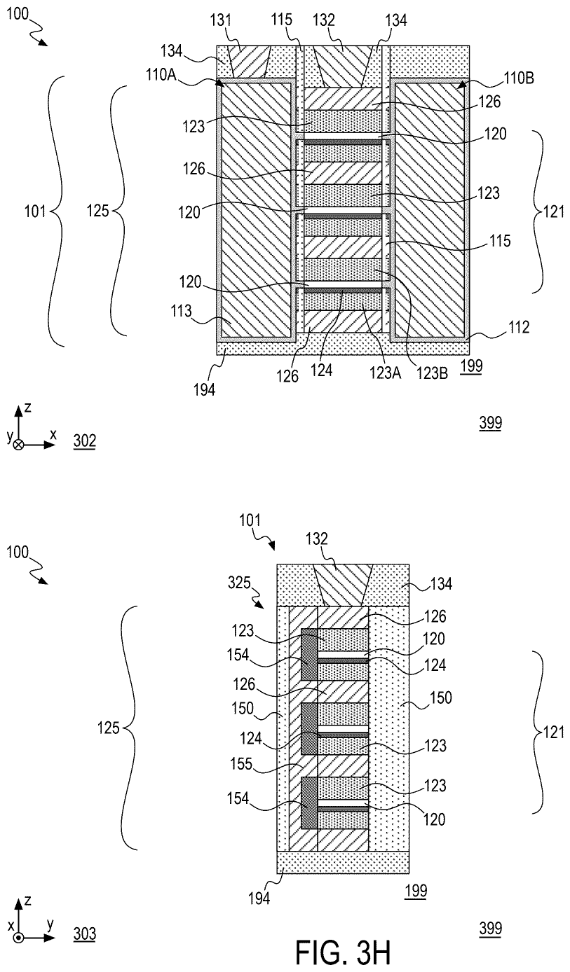

FIGS. 3A, 3B, 3C, 3D, 3E, 3F, 3G, and 3H illustrate plan and cross-sectional views 301, 302 of an IC device 100 with transistor structures 101 having stacks 121 of 2D channel layers 120, at various stages of manufacture, in accordance with some embodiments. FIGS. 3A-3H show possible examples of intermediate structures during an embodiment of a practice of methods 200 of FIG. 2.

Returning to FIG. 2, methods 200 begin at operation 201 with depositing a template layer over a substrate. The template layer may be of any suitable material(s), for example, a preferential growth material for a base layer of a layer stack. The template layer may serve as guide or template for the subsequent growth (e.g., epitaxial deposition) of overlying layers. The template layer advantageously includes a low-k dielectric material, as the template layer may serve as isolation between the subsequently grown material layers and the underlying substrate (much as described of isolation layer 194 at FIG. 1A). In many embodiments, the template layer has a crystalline structure. In many embodiments, the template layer includes oxygen, for example, in a metal (or other) oxide. In some such embodiments, the template layer includes one of aluminum, hafnium, or silicon. For example, the template layer may be or include a substantially monocrystalline lattice of an aluminum oxide (such as Al₂O₃), hafnium oxide (such as HfO₂), or silicon oxide (such as SiO₂).

The template layer may be deposited by any suitable means. In many embodiments, the template layer is deposited on the substrate by a chemical vapor deposition (CVD). The substrate (e.g., an IC die or wafer, much as described of substrate 199 at FIG. 1A) may be formed or received by any suitable means.

Returning to FIG. 2, methods 200 continue at operation 202 with patterning a mask layer over the template layer, for example, with openings in the mask layer where a layer stack may be subsequently deposited. The mask layer openings may provide a constrained area for controlled (e.g., monocrystalline) growth of a subsequent channel material layer. The mask layer may be of any suitable material(s), for example, a non-preferential growth material for a base layer of a layer stack. The mask layer may inhibit (or at least provide less affinity for) the growth of subsequent layers. In some embodiments, the mask layer has a non-crystalline structure. In some embodiments, the mask layer has a crystalline structure, but with a lattice not suitable for epitaxial deposition of a stack base layer. In some embodiments, the mask layer includes carbon (e.g., diamond) or both silicon and oxygen (e.g., in an oxide of silicon, SiOₓ).

The mask layer may be patterned by any suitable means. In many embodiments, the mask layer is deposited over the template layer by CVD. In many embodiments, one or more openings are formed in the mask layer by photolithographic (or other suitable) means.

In many embodiments, portions of the template layer are exposed in openings of the mask layer. The mask layer openings enable the subsequent deposition of a layer stack on the exposed portions of the template layer.

FIG. 3A shows mask layer 350 over template layer 194 in a workpiece or IC device 100, in accordance with some embodiments, for example, following a performance of depositing and patterning operations 201 and 202. Template layer 194 is over substrate 199 and visible through openings 351 in mask layer 350, as illustrated in plan view 301. Exposed portions 394 of template layer 194 are available, e.g., as a growth template, through openings 351 in mask layer 350, as shown in profile view 302. Mask layer 350 may have any suitable height over template layer 194, for example, a height tall enough to confine or constrain preferential TMD deposition to template layer 194 and subsequently deposited layer over exposed portions 394 of layer 194. Exposed portions 394 may be recessed in template layer 194, if desired, e.g., by etching through openings 351 in mask layer 350.

Returning to FIG. 2, methods 200 continue by depositing a metal on the template layer at operation 203. The deposited metal may form a portion of a gate electrode (much as described of gate electrode 126 at FIG. 1A, etc.) in a gate stack over and under channel layers. In many embodiments, depositing the metal deposits the metal on at least the exposed portion(s) of the template layer. In some embodiments, depositing the metal deposits the metal on the mask layer. In at least some such embodiments, any metal deposited on the mask layer is of a lower quantity (e.g., thickness) and quality than the metal preferentially deposited on the template layer. For example, metal preferentially deposited on the template layer may have more (e.g., a higher density of) and superior nucleation sites than metal deposited on the mask layer, which may adhere to the mask layer poorly and be easily removed. The metal may be removed from over the mask layer before other operations following the metal deposition or later in methods 200, e.g., as described further at operation 209.

The metal may be deposited by any suitable means, for example, by CVD. In many embodiments, the metal is epitaxially deposited in a crystalline lattice structure, which may provide a preferential growth template for subsequently deposited layers. In some embodiments, the metal is deposited by ALD (atomic layer deposition).

The “metal” may be of any suitable material(s), for example, crystalline materials having sufficient conductivity, including satisfactory ceramics, etc. In some embodiments, the metal includes nitrogen, e.g., in a nitride of metal. In some embodiments, the metal includes titanium. In some embodiments, the metal includes titanium and nitrogen, e.g., in a nitride, such as titanium nitride (e.g., TiN). In some embodiments, multiple metals are deposited at operation 203, e.g., in distinct layers, such as work function and fill layers (much as described of gate electrode 126 at FIG. 1A). In some such embodiments, the multiple metal layers all have crystalline structures, which may enable continued epitaxial deposition of the gate stack layers (e.g., with each metal layer serving as a template for the next-formed layer).

FIG. 3B illustrates bottom layers of gate electrode 126 on template layer 194 in openings 351 of mask layer 350 in workpiece or device 100, in accordance with some embodiments, for example, following a performance of depositing operation 203. The material of gate electrode 126 may also be deposited (e.g., non-preferentially or inadvertently) in layer 326 on mask layer 350. Bottom layers of gate electrode 126 are visible through openings 351 in mask layer 350, as shown in plan view 301, which also shows electrode-material layer 326 over mask layer 350. Profile view 302 also illustrates layers of gate electrode 126 on template layer 194 in openings 351 and electrode layer 326 on mask layer 350.

Returning to FIG. 2, methods 200 continue with forming a dielectric layer on the metal at operation 204. The dielectric layer formed may be a gate insulator layer (much as described of layer 123A at FIG. 1A, etc.) in a gate stack between channel layers. In many embodiments, forming the dielectric layer on the metal forms the dielectric layer on the metal on the exposed portion of the template layer (e.g., whether or not a dielectric layer is also formed on the mask layer). Any dielectric layer formed over the mask layer may be removed immediately following the dielectric deposition or later in methods 200, e.g., as described further at operation 209. The dielectric layer may be deposited by any suitable means, for example, by CVD, such as metalorganic CVD (MOCVD). In many embodiments, the dielectric layer is epitaxially deposited in a crystalline lattice structure, which may provide a preferential growth template for subsequently deposited layers. In some embodiments, the dielectric layer is deposited by ALD.

The dielectric layer may be of any suitable material(s), for example, crystalline materials of sufficient electrical resistivity. In many embodiments, the dielectric layer includes oxygen (e.g., in an oxide dielectric layer). In some embodiments, the dielectric layer includes a metal (e.g., in a metal oxide). In some such embodiments, the included metal is aluminum or hafnium (e.g., in a metal oxide). The dielectric layer metal may be the same metal or a different metal (e.g., a second metal) than the metal deposited at operation 203 (e.g., on the template layer and under the dielectric layer). In some embodiments, forming the dielectric layer includes epitaxially depositing oxygen and either aluminum or hafnium in a crystalline lattice structure. For example, the dielectric layer may be epitaxially grown as a substantially monocrystalline lattice of an aluminum oxide (such as Al₂O₃) or hafnium oxide (such as HfO₂). Other suitable materials may be deployed.

FIG. 3C shows gate insulator layers 123A on bottom layers of gate electrode 126 in openings 351 of mask layer 350 in workpiece or IC device 100, in accordance with some embodiments, for example, following a performance of forming operation 204. The insulator material of layers 123A may also be deposited (e.g., non-preferentially or inadvertently) in layer 323 over mask layer 350 (e.g., either on mask layer 350 or on a material deposited over layer 350, such as layer 326, as described at operation 203 and FIG. 3B). Insulator layers 123A are visible through openings 351 in mask layer 350, as illustrated in plan view 301, which also shows insulator-material layer 323 over mask layer 350. Profile view 302 also shows layer 323 over mask layer 350 and layers 123A on bottom layers of gate electrode 126 in openings 351. In the exemplary embodiment of FIG. 3C, insulator layer 323 is directly on mask layer 350, but in other embodiments, insulator layer 323 may be on another material (such as layer 326, as described elsewhere herein) over mask layer 350. Layer 323 (and layer 326, etc.) may be removed from over mask layer 350 immediately following deposition or later, e.g., together in a single removal operation, etc., (for example, as described further at operation 209).

Returning to FIG. 2, methods 200 continue at operation 205 by treating the dielectric layer with a reactant. The treating may functionalize an upper surface of the dielectric layer and enable directed growth of a subsequently grown channel layer (e.g., in a desired direction and to desired dimensions). Any suitable reactant may be utilized. In many embodiments, the reactant includes an element not present in the dielectric layer. For example, the dielectric layer may be treated with a reactant that includes phosphorus, which may functionalize the upper surface of the dielectric layer. In many embodiments, the reactant is or includes phosphine (PH₃). In some embodiments, the reactant is or includes tris(dimethylamino)phosphine (P(NMe₂)₃, where Me=methyl, CH₃). The reactant may be P(NR2)3, where R is any group in which a carbon or hydrogen atom is attached to the rest of the molecule. In other embodiments, the reactant is or includes P(OR)3, where R is any group in which a carbon or hydrogen atom is attached to the rest of the molecule. One or more other elements (e.g., besides phosphorus), and one or more other reactants (e.g., with or without phosphorus), may be employed.

The treating the dielectric layer may be by any suitable means. In many embodiments, treating the dielectric layer with the reactant forms an interface layer on the dielectric layer, and the interface layer includes the element not in the dielectric layer (e.g., phosphorus). The interface layer formed may be much as described of layer 124 at FIG. 1A, etc., in a gate stack between channel layers. For example, the treatment of the upper (e.g., oxide) surface of the dielectric layer by the reactant (e.g., tris(dimethylamino)phosphine) may result in protonation of the amino groups by hydroxyl groups of the surface. The amino groups may leave as HNMe₂, and the phosphorus may interact with (e.g., bond with oxygen atoms of), and remain on, the surface. The interface layer formed may then be a monolayer of phosphorus on the oxygen and/or metal in the dielectric layer, between the oxygen and/or metal in the dielectric layer and a subsequently formed channel material layer.

Any interface layer formed (or deposition of the element) over the mask layer may be removed immediately following the formation or deposition or later in methods 200 (e.g., as described further at operation 209), for example, with the dielectric layer formed (at operation 204) on the gate electrode layer.

FIG. 3D illustrates interface layers 124 on dielectric layers 123A in openings 351 of mask layer 350 in workpiece or device 100, in accordance with some embodiments, for example, following a performance of treating operation 205. Interface layers 124 are visible through openings 351, as shown in plan view 301, which also shows mask layer 350, exposed between openings 351 and separating layers 124. Profile view 302 also illustrates mask layer 350, not covered between openings 351, and layers 124 separated by mask layer 350, on layers 123A (in turn on bottom layers of gate electrode 126) in openings 351. In the exemplary embodiment of FIG. 3D, an upper surface of mask layer 350 is not covered between openings 351, but in other embodiments, mask layer 350 is covered between openings 351, e.g., by layers 323, 326, as described elsewhere herein. Interface layers may also be over mask layer 350 (e.g., on a material deposited over layer 350, such as layer 323, as described at operation 204 and FIG. 3C).

Returning to FIG. 2, methods 200 continue at operation 206 with forming a channel material layer on the treated dielectric layer. In many embodiments, the channel material layer includes a chalcogen and a metal. The channel material layer formed may be a channel layer (much as described of layer 120 at FIG. 1A, etc., such as a 2D layer) in a stack of channel layers extending through a gate stack. In many embodiments, the formed channel material layer is on the treated dielectric layer on the metal on the exposed portion of the template layer (e.g., within a constrained area in the mask layer opening). Any inadvertently deposited channel material (e.g., the chalcogen and metal) may be removed from over the mask layer before other operations following the channel material deposition or later in methods 200, e.g., as described further at operation 209. The channel material layer may be deposited by any suitable means, for example, by CVD. In many embodiments, the channel material layer is epitaxially deposited in a crystalline lattice structure, which may provide a preferential growth template for subsequently deposited layers. In some embodiments, the channel material layer is deposited by ALD.

The channel material layer may be of any suitable material(s), for example, crystalline materials having semiconductor characteristics, such as TMD with a 2H phase. In many embodiments, the channel material layer includes chalcogen (such as sulfur or selenium). In many embodiments, the channel material layer includes a metal (such as tungsten or molybdenum). The channel material layer metal may be the same metal or a different metal (e.g., a third metal) than the first metal deposited at operation 203 or a second metal in the dielectric layer formed at operation 204. In some embodiments, forming the channel material layer includes epitaxially depositing the chalcogen and the metal (such as tungsten or molybdenum) in a crystalline lattice structure (e.g., different than the crystalline structures of the gate electrode metal or the dielectric layer). For example, the channel material layer may be epitaxially grown as a substantially monocrystalline lattice of a 2H TMD (such as MoS₂, MoSe₂, WS₂, WSe₂, etc.). Other suitable materials may be deployed.

The growth of the channel material layer may be directed by the interface layer (e.g., formed by treating operation 205), for example, the element in the interface layer, and the mask layer may prevent the formation of grain boundaries during crystal growth. The mask layer may ensure monocrystalline growth of channel material (e.g., of single-crystal channel layers) by confining growth areas of individual channel material layers, which may limit individual channel layers to a single nucleation site per opening in the mask layer.

The interface layer may also regulate channel growth. In many embodiments, the presence of the interface layer (and the element in the interface layer) directs the growth of the channel material layer, e.g., in a single, lateral dimension (such as a channel length), rather than in multiple lateral dimensions (such as both a channel length and width) without the interface layer and element. In some embodiments, the growth of the channel material layer is directed in a channel length dimension, and the channel width is correlated with a concentration of the element in the interface layer.

FIG. 3E shows channel material layers 120 (e.g., 2D layers 120) on interface layers 124 (on dielectric layers 123A) in workpiece or device 100, in accordance with some embodiments, for example, following a performance of forming operation 206. Channel material layers 120 are visible through openings 351, as illustrated in plan view 301, which also shows mask layer 350, exposed between openings 351 and separating layers 120. Profile view 302 also shows mask layer 350, not covered between openings 351, and layers 120 separated by mask layer 350, on layers 124 (in turn on layers 123A on bottom layers of gate electrode 126) in openings 351. In the exemplary embodiment of FIG. 3E, an upper surface of mask layer 350 is not covered between openings 351, but in other embodiments, mask layer 350 is covered between openings 351, e.g., by layers 323, 326, as described elsewhere herein, and channel material layers on interface layers which may also be over layers 323, 326, 350.

Returning to FIG. 2, methods 200 continue by forming a dielectric layer on the channel material layer at operation 207. The dielectric layer formed may be a gate insulator layer (much as described of layer 123B at FIG. 1A, etc.) in a gate stack between channel layers. In many embodiments, this second dielectric layer (over the channel material layer) is similar to the first dielectric layer (formed at operation 204, under the channel material and interface layers), e.g., having the same composition, for example, of a metal oxide. Notably, the second dielectric layer is similar to the first dielectric layer, but the second dielectric layer may be formed by epitaxially depositing the insulator material of the second dielectric layer (e.g., oxygen and either aluminum or hafnium) with the channel material layer as a template or preferential growth material rather than the gate electrode material (e.g., a metal, deposited at operation 203).

The second dielectric layer (over the channel material layer) may include any suitable material(s). In some embodiments, forming the second dielectric layer includes epitaxially depositing the composition of first dielectric layer (e.g., oxygen and either aluminum or hafnium) in a same or identical (but separate) crystalline lattice structure, which may provide a preferential growth template for subsequently deposited layers. For example, the second dielectric layer may be epitaxially grown as a substantially monocrystalline lattice of an aluminum oxide (such as Al₂O₃) or hafnium oxide (such as HfO₂), but over the channel material layer. Other suitable materials may be deployed. The dielectric layer may be deposited by any suitable means, for example, by CVD, such as MOCVD. In some embodiments, the dielectric layer is deposited by ALD.

A second dielectric layer (e.g., of a metal oxide) may also be formed (e.g., non-preferentially or inadvertently deposited) over the mask layer (e.g., either on the mask layer or on a material deposited over the mask layer, such as the channel material, as described at operation 207). The second dielectric layer may be removed from over the mask layer before other operations following the dielectric deposition or later in methods 200.

Returning to FIG. 2, methods 200 optionally continue with forming a stack of the channel material layers at operation 208. The stack may be formed by similar means as those described at operations 203 through 207, e.g., to form second, third, etc., portions of the stack over the first portion formed at operations 203 through 207. Notably, at operation 208, the first metal (e.g., a gate electrode metal deposited on the template layer at operation 203) is deposited on the uppermost layer of the first-formed portion, e.g., on the dielectric layer over the channel material layer, rather than depositing the first metal on a (dielectric) template layer. A third dielectric layer (e.g., an insulator layer 123A including the second metal in the first composition, such as a metal oxide) may then be formed on the gate electrode metal on the second dielectric layer (e.g., by the same means the first dielectric layer was formed at operation 204). The third dielectric layer may then be treated with the reactant (e.g., by the same means the first interface layer was treated (for example, functionalized), and the interface layer formed, at operation 205). A second channel material layer (e.g., including the chalcogen and the third metal) may then be formed on the treated third dielectric layer (e.g., by the same means the first channel material layer was formed, at operation 206). A fourth dielectric layer (e.g., an insulator layer 123B including the second metal in the first composition, such as a metal oxide) may then be formed on the second channel material layer (e.g., by the same means the second dielectric layer was formed, at operation 207). Subsequent stack portions may be formed by repeating operations 203 through 207 (with the noted alteration for depositing the gate electrode metal on the underlying dielectric layer).

Returning to FIG. 2, methods 200 continue at operation 209 by removing the gate electrode, dielectric, interface, and/or channel materials from over the mask layer. The materials may be removed by any suitable means, for example, by CMP (chemical mechanical polish or planarization). A CMP may polish and planarize an upper surface of the substrate by removing any materials deposited on and over the mask layer, including the gate electrode material (e.g., of the first metal, as deposited at operation 203), the dielectric material (e.g., of oxygen and the second metal, as deposited at operations 204, 207), the element of the reactant (e.g., as deployed at operation 205), the channel material (e.g., of a chalcogen and the third metal, as deposited at operation 206), etc. The openings in the mask layer may be filled (e.g., up to at least an upper surface of the mask layer) with a sacrificial material before planarizing. The sacrificial material may be selectively removed (e.g., by an etch) following planarization.

Operation 209 may be employed at any suitable point(s) throughout methods 200. The various materials (metals, chalcogen, etc.) may be removed once, collectively, after the layer stack is formed; individually, after each layer is deposited; or at multiple times, multiple layers at a time, e.g., once per iterative stack portion (for example, after depositing a layer (dielectric, channel, etc.) having a satisfactory etch selectivity between that top layer and the sacrificial fill material). For example, if stacks of multiple channel and gate material layers are to be formed (e.g., at operation 208) and, e.g., a gate electrode material (deposited at operation 203) has a good etch selectivity with a sacrificial fill material, the gate electrode material may function as an etch-stop layer. The mask openings may be filled with sacrificial material after each deposition of the gate electrode material (e.g., covering any material layers in the mask openings), the various materials may be removed from over the mask layer by CMP, and the sacrificial fill material may be removed from the mask openings by selective etch, down to the etch-stop layer of gate electrode material. A next, iterative portion of the material stack may then be formed over the gate electrode material. In many embodiments, the various materials are removed once (e.g., collectively, by CMP, after the entire layer stack is formed), and a sacrificial fill material is then removed from the mask openings (e.g., by a selective etch).

FIG. 3F illustrates stacks 121, 125 of material layers in workpiece or device 100, in accordance with some embodiments, for example, following a performance of forming operations 207 and 208 and removing operation(s) 209. In embodiments, mask layer 350 has a height as tall as necessary to constrain (e.g., control) the growth of material layers (e.g., 2D channel layers 120) in openings 351. Profile view 302 shows gate insulator layer 123B on channel material layer 120 (for example, following a performance of forming operation 207) and stacks 121 of channel layers 120 extending through gate stacks 125 (for example, following a performance of forming operation 208). Gate stacks 125 include a bottom layer of gate electrode 126, as well as layers of gate electrode 126 on each of layers 123B. Pairs of gate insulator layers 123A, 123B are between each pair of layers of gate electrode 126, and a channel layer 120 is between each pair of gate insulator layers 123A, 123B. Stacks 121 include channel layers 120 extending through gate stacks 125, e.g., with layers of gate electrode 126 under, over, and between channel layers 120.

View 302 also illustrates mask layer 350 not covered between openings 351, for example, following the removal of layers 323, 326 (as described at FIGS. 3B, 3C) at operation 209, as well as the removal of interface and channel material layers (e.g., as formed at operations 205, 206).

Returning to FIG. 2, methods 200 continue at operation 210 with removing the mask layer from over the substrate. Some or all of the mask layer may be removed from over the substrate, e.g., from between layer stacks, by any suitable means. In many embodiments, the mask layer is removed by a selective etch. The removal of the mask layer may expose sidewalls of the layer stack(s), including ends and/or sidewalls of the channel material layers. Different sections of the mask layer may be removed separately, for example, to first expose certain stack sidewalls, while leaving others masked until further processing.

FIG. 3G shows exposed sidewalls of stacks 121, 125 of material layers and no mask layer present between stacks 121, 125 in workpiece or device 100, in accordance with some embodiments, for example, following a performance of removing operation 210. Sidewalls of stacks 121, 125 are exposed between stacks 121, 125, and exposed sidewalls of stacks 121 may be or include exposed ends of channel layers 120.

Returning to FIG. 2, methods 200 continue by forming a gate structure in a transistor structure at operation 211. The gate stack may be formed by any suitable means. In some embodiments, the gate stack is formed by depositing the first (e.g., gate electrode) metal over the dielectric layer on an uppermost channel material layer, forming sidewalls of a dielectric material to both sides of the channel material layer(s) and each of the dielectric layers over and under each channel material layer, and coupling the lowermost layer of the first metal (e.g., on the template layer) with the uppermost layer of the first metal (e.g., over the dielectric layer on an uppermost channel material layer). The layers of the first metal (e.g., lowermost, uppermost, and any layers of the first metal between channel material layers) may be coupled together in (e.g., to form) a gate electrode.

The first metal may be deposited over the dielectric layer (e.g., the second dielectric layer) on an uppermost channel material layer by any suitable means, for example, much as described at operation 207.

The sidewalls of dielectric material (e.g., first and second sidewalls, with each channel material layer and the dielectric layers over and under each channel material layer between a pair of first and second sidewalls) may be formed by any suitable means. In some embodiments, the dielectric material is selectively grown (e.g., deposited) on the sidewalls of each channel material layer and the nearest dielectric layers, directly over and under each channel material layer. In such embodiments with a stack of multiple channel material layers, each channel material layer and pair of nearest dielectric layers are between a pair of sidewalls of dielectric material, and each pair of dielectric-material sidewalls may be over or under another pair of dielectric-material sidewalls with a gate electrode layer between vertically adjacent dielectric-material sidewalls. In some embodiments, a blocking material is selectively grown on sidewalls of the gate electrode material, and the dielectric-material sidewalls are preferentially deposited on the channel material and dielectric layers, but not (or poorly) on the blocking material. The blocking material may then be removed, exposing the gate electrode material.

The layers of the first metal (e.g., lowermost, uppermost, and any layers of the gate electrode metal between channel material layers) may be coupled together by any suitable means, for example, by conformally depositing a metal (e.g., a liner metal) on exposed sidewalls of the multiple layers of the gate electrode material.

FIG. 3H illustrates gate structure 325 in transistor structure 101 in IC device 100, in accordance with some embodiments, for example, following a performance of forming operation 211. Profile view 302 shows a cross-sectional profile view of transistor structure 101 with an x- z viewing plane through stacks 121, 125 and source and drain terminals 110. Nanoribbon channel layers 120 of stack 121 extend between source and drain terminals 110 and through gate stack 125. Profile view 303 illustrates a cross-sectional profile view of transistor structure 101 with a y-z viewing plane through gate stack 125 and between the source and drain terminals (not shown, e.g., in front of and behind the y-z viewing plane).

Gate structure 325 includes gate electrode 126, stack 125, and insulators 154. Gate electrode 126 includes vertical portion 155, which couples the layer portions of electrode 126 in gate stack 125. Gate insulators 154 provide electrical isolation, e.g., between electrode 126 portion 155 and channel layers 120. Gate insulators 154 are contiguous with gate insulator layers 123. Collectively, gate insulators 154 layers 123 electrically insulate channel layers 120 from gate electrode 126.

Gate via 132 through isolation material 134 couples electrode 126 to an interconnect network (not shown), for example, over transistor structure 101 and electrode 126. Contact vias 131 through isolation material 134 couple source and drain terminals 110 to an interconnect network (not shown), for example, over transistor structure 101 and terminals 110. The interconnect network (not shown) may electrically couple transistor structure 101 to a power supply.

IC device 100 may include or be coupled to a substrate or other host component 399. Host component 399 may be a package substrate, an interposer, an IC die, etc. For example, substrate 199 may be an IC die that includes transistor structures 101, substrate 199 may be coupled (e.g., soldered or otherwise bonded) to host component 399, and transistor structure 101 may be coupled to a power supply (not shown) through host component 399.

Host component 399 is a planar platform and may include dielectric and metallization structures. Host component 399 mechanically supports and electrically couples one or more IC devices 100. At least one side of host component 399 includes substrate interconnect interfaces for bonding to one or more IC devices 100. IC device 100 may be direct bonded, e.g., hybrid bonded, to host component 399 or otherwise bonded, e.g., by optional solder bumps. The opposite side of host component 399 may include similar interfaces, e.g., copper pads for socketing and/or solder bumps for bonding device 100 to a host component, such as a printed circuit board (PCB). Host component 399 may be any host component with substrate interconnect interfaces, such as a package host component 399 or interposer, etc. Host component 399 may itself be a die. In many embodiments, host component 399 includes organic dielectric(s), such as a resin or other polymer, between metallization layers.

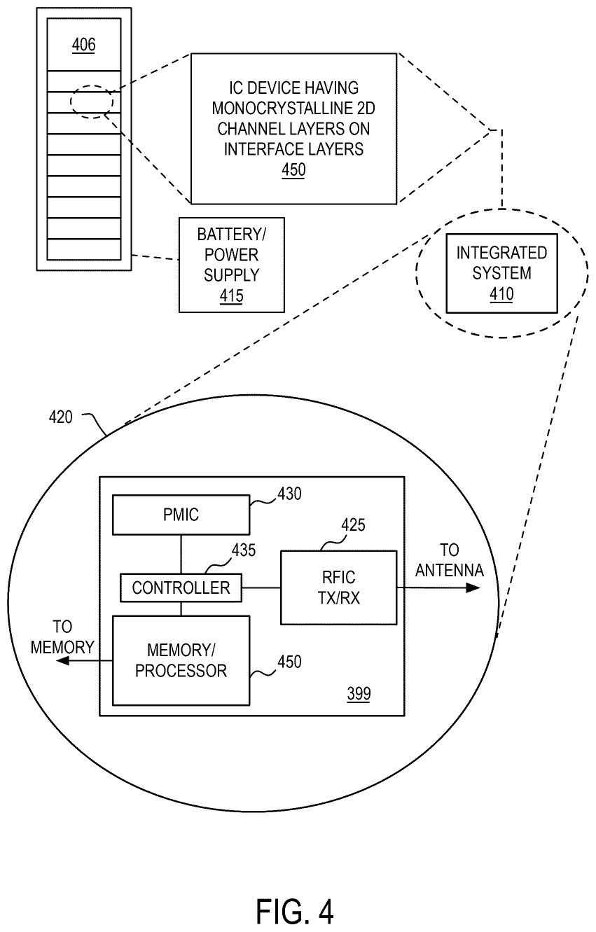

FIG. 4 illustrates a diagram of an example data server machine 406 employing an IC device having monocrystalline 2D channel layers and interface layers between the channel layers and underlying gate dielectrics, in accordance with some embodiments. Server machine 406 may be any commercial server, for example, including any number of high-performance computing platforms disposed within a rack and networked together for electronic data processing, which in the exemplary embodiment includes one or more devices 450 having monocrystalline 2D channel layers on interface layers.

Also as shown, server machine 406 includes a battery and/or power supply 415 to provide power to devices 450, and to provide, in some embodiments, power delivery functions such as power regulation. Devices 450 may be deployed as part of a package-level integrated system 410. Integrated system 410 is further illustrated in the expanded view 420. In the exemplary embodiment, devices 450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 450 is a microprocessor including a static RAM (SRAM) cache memory. As shown, device 450 may be an IC device having monocrystalline 2D channel layers on interface layers, as discussed herein. Device 450 may be further coupled to (e.g., communicatively coupled to) a board, an interposer, or other substrate or host component 399 along with, one or more of a power management IC (PMIC) 430, RF (wireless) IC (RFIC) 425 including a wideband RF (wireless) transmitter and/or receiver (TX/RX) (e.g., including a digital baseband and an analog front end module further includes a power amplifier on a transmit path and a low noise amplifier on a receive path), and a controller 435 thereof. In some embodiments, RFIC 425, PMIC 430, controller 435, and device 450 include having monocrystalline 2D channel layers on interface layers.

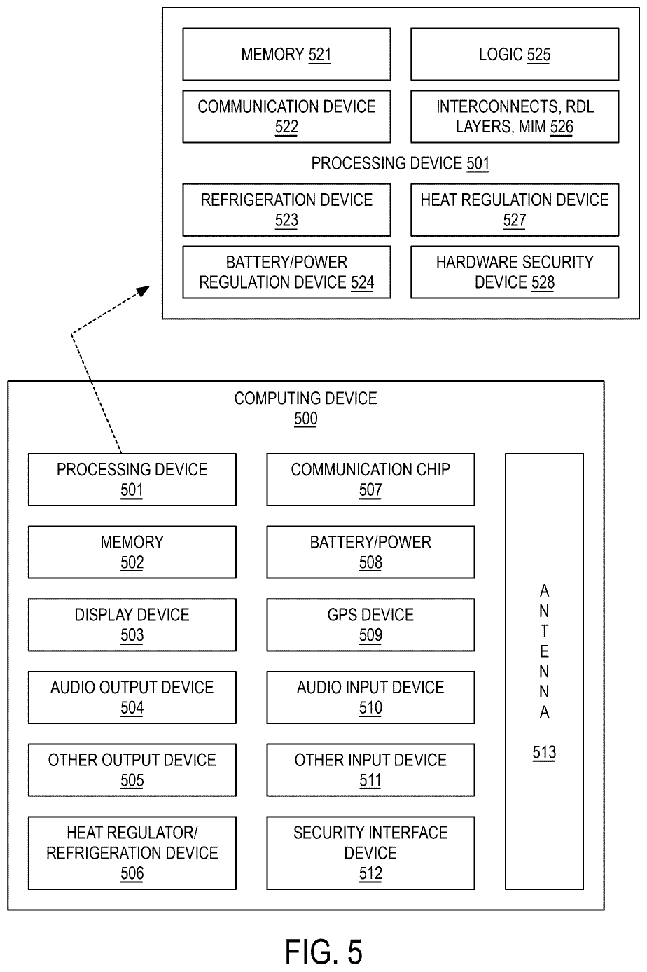

FIG. 5 is a block diagram of an example computing device 500, in accordance with some embodiments. For example, one or more components of computing device 500 may include any of the devices or structures discussed herein. A number of components are illustrated in FIG. 5 as being included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled. In another set of examples, computing device 500 may not include an audio output device 504, other output device 505, global positioning system (GPS) device 509, audio input device 510, or other input device 511, but may include audio output device interface circuitry, other output device interface circuitry, GPS device interface circuitry, audio input device interface circuitry, audio input device interface circuitry, to which audio output device 504, other output device 505, GPS device 509, audio input device 510, or other input device 511 may be coupled.

Computing device 500 may include a processing device 501 (e.g., one or more processing devices). As used herein, the term “processing device” or “processor” indicates a device that processes electronic data from registers and/or memory to transform that electronic data into other electronic data that may be stored in registers and/or memory. Processing device 501 may include a memory 521, a communication device 522, a refrigeration device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 500 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 502 includes memory that shares a die with processing device 501. This memory may be used as cache memory and may include embedded dynamic random-access memory (eDRAM) or spin transfer torque magnetic random-access memory (STT-MRAM).

Computing device 500 may include a heat regulation/refrigeration device 506. Heat regulation/refrigeration device 506 may maintain processing device 501 (and/or other components of computing device 500) at a predetermined low temperature during operation.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a GPS device 509 (or corresponding interface circuitry, as discussed above). GPS device 509 may be in communication with a satellite-based system and may receive a location of computing device 500, as known in the art.

Computing device 500 may include other output device 505 (or corresponding interface circuitry, as discussed above). Examples of the other output device 505 may include an audio codec, a video codec, a printer, a wired or wireless transmitter for providing information to other devices, or an additional storage device.

Computing device 500 may include other input device 511 (or corresponding interface circuitry, as discussed above). Examples of the other input device 511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, access list management, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-5. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first terminal and a second terminal in a transistor structure, a stack of nanoribbons between the first and second terminals, wherein each of the nanoribbons includes a metal and a chalcogen, a gate stack in the transistor structure and between the first and second terminals, the gate stack including an electrode material between the nanoribbons and an insulator material between the nanoribbons and the electrode material, and an interface layer between each of the nanoribbons and the insulator material, the interface layers including an element not present in the insulator material or present in a first concentration in the interface layers greater than a thousand times a second concentration of the element in the insulator material.

In one or more second embodiments, further to the first embodiments, the gate stack includes the insulator material in first and second layers, the first layers under the nanoribbons and the second layers over the nanoribbons, each of the second layers is on the corresponding nanoribbon, each of the nanoribbons is on a corresponding interface layer between one of the first layers and the corresponding nanoribbon, and the element is not present in the insulator material or the nanoribbons.

In one or more third embodiments, further to the first or second embodiments, the element is phosphorus, the metal is a first metal, and the insulator material includes oxygen and a second metal different than the first metal.

In one or more fourth embodiments, further to the first through third embodiments, a first of the interface layers is a monolayer of the element in contact with the insulator material and a first of the nanoribbons, the first of the interface layers is over the insulator material, and the first of the nanoribbons is over the first of the interface layers.

In one or more fifth embodiments, further to the first through fourth embodiments, the insulator material is on an upper surface of a first of the nanoribbons, the first of the nanoribbons is on an upper surface of a first of the interface layers, a lower surface of the first of the interface layers is on the insulator material, and the first of the interface layers has a thickness of less than 0.5 nm.

In one or more sixth embodiments, further to the first through fifth embodiments, the metal is tungsten or molybdenum, and the chalcogen is sulfur or selenium.

In one or more seventh embodiments, further to the first through sixth embodiments, a first of the nanoribbons includes the metal in a first atomic plane between second and third atomic planes of the chalcogen.

In one or more eighth embodiments, further to the first through seventh embodiments, the metal is a first metal, the gate stack includes the insulator material in first and second layers, the first layers under the nanoribbons and the second layers over the nanoribbons, and a portion of the transistor structure includes a first of the nanoribbons including a first crystalline structure having the first metal in a first atomic plane between second and third first atomic planes of the chalcogen, a first of the first layers under the first of the nanoribbons, the insulator material in the first of the first layers including a second crystalline structure of oxygen and a second metal different than the first metal, a first of the second layers over the first of the nanoribbons, the insulator material in the first of the second layers including the second crystalline structure of oxygen and the second metal, and the electrode material under the first of the first layers and over the first of the second layers, the electrode material including a third metal in a third crystalline structure.

In one or more ninth embodiments, further to the first through eighth embodiments, the first metal is tungsten or molybdenum, the chalcogen is sulfur or selenium, the second metal is aluminum or hafnium, and the third metal is titanium, the electrode material also including nitrogen in the third crystalline structure.

In one or more tenth embodiments, an apparatus includes a first terminal and a second terminal in a transistor structure in a substrate, a gate stack in the transistor structure and between the first and second terminals, the gate stack including an electrode material and a gate dielectric, a stack of channel material layers extending through the gate stack between the first and second terminals, wherein the channel material layers include a metal and a chalcogen, the gate dielectric is in first and second layers between the channel material layers and the electrode material, the first layers are under corresponding ones of the channel material layers, and the second layers are over the corresponding ones of the channel material layers, and a plurality of interface layers between the first layers and the corresponding ones of the channel material layers, the interface layers including phosphorus.

In one or more eleventh embodiments, further to the tenth embodiments, the interface layers are monolayers of phosphorus on the first layers, the channel material layers are on the interface layers, and the second layers are on the channel material layers.

In one or more twelfth embodiments, further to the tenth or eleventh embodiments, the metal is tungsten or molybdenum, and the chalcogen is sulfur or selenium.

In one or more thirteenth embodiments, further to the tenth through twelfth embodiments, the electrode material includes titanium and nitrogen.

In one or more fourteenth embodiments, further to the tenth through thirteenth embodiments, the substrate is coupled to a host component, and the transistor structure is coupled to a power supply through the host component.

In one or more fifteenth embodiments, a method includes depositing a template layer over a substrate, depositing a first metal on the template layer, patterning a mask layer over the template layer, wherein portions of the template layer are exposed in openings of the mask layer, forming a first dielectric layer on the first metal, the first dielectric layer including a second metal in a first composition, forming a channel material layer on the first dielectric layer, the channel material layer including a chalcogen and a third metal, and forming a second dielectric layer on the channel material layer, the second dielectric layer having the first composition.

In one or more sixteenth embodiments, further to the fifteenth embodiments, the method also includes treating the first dielectric layer with a reactant including an element not present in the first composition.

In one or more seventeenth embodiments, further to the fifteenth or sixteenth embodiments, the treating the first dielectric layer with the reactant forms an interface layer on the first dielectric layer, the interface layer including the element.

In one or more eighteenth embodiments, further to the fifteenth through seventeenth embodiments, the element is phosphorus, and the interface layer is a monolayer of phosphorus between the channel material layer and the second metal in the first dielectric layer.

In one or more nineteenth embodiments, further to the fifteenth through eighteenth embodiments, the depositing the first metal includes epitaxially depositing titanium with nitrogen in a first crystalline structure, the forming the first dielectric layer includes epitaxially depositing oxygen and aluminum or hafnium in a second crystalline structure, the forming the channel material layer includes epitaxially depositing sulfur or selenium with tungsten or molybdenum in a third crystalline structure, and the forming the second dielectric layer includes epitaxially depositing oxygen and aluminum or hafnium in the second crystalline structure.

In one or more twentieth embodiments, further to the fifteenth through nineteenth embodiments, the method also includes removing the first metal, the second metal, the third metal, or the chalcogen from over the mask layer, and removing the mask layer from over the substrate.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first terminal and a second terminal in a transistor structure;
a stack of nanoribbons between the first and second terminals, wherein each of the nanoribbons comprises a metal and a chalcogen;
a gate stack in the transistor structure and between the first and second terminals, the gate stack comprising an electrode material between the nanoribbons and an insulator material between the nanoribbons and the electrode material; and
an interface layer between each of the nanoribbons and the insulator material, the interface layers comprising an element not present in the insulator material or present in a first concentration in the interface layers greater than a thousand times a second concentration of the element in the insulator material.

2. The apparatus of claim 1, wherein:
the gate stack comprises the insulator material in first and second layers, the first layers under the nanoribbons and the second layers over the nanoribbons;
each of the second layers is on the corresponding nanoribbon;
each of the nanoribbons is on a corresponding interface layer between one of the first layers and the corresponding nanoribbon; and
the element is not present in the insulator material or the nanoribbons.

3. The apparatus of claim 1, wherein:
the element is phosphorus;
the metal is a first metal; and
the insulator material comprises oxygen and a second metal different than the first metal.

4. The apparatus of claim 1, wherein:
a first of the interface layers is a monolayer of the element in contact with the insulator material and a first of the nanoribbons;
the first of the interface layers is over the insulator material; and
the first of the nanoribbons is over the first of the interface layers.

5. The apparatus of claim 1, wherein:
the insulator material is on an upper surface of a first of the nanoribbons;
the first of the nanoribbons is on an upper surface of a first of the interface layers;
a lower surface of the first of the interface layers is on the insulator material; and
the first of the interface layers has a thickness of less than 0.5 nm.

6. The apparatus of claim 1, wherein the metal is tungsten or molybdenum, and the chalcogen is sulfur or selenium.

7. The apparatus of claim 1, wherein a first of the nanoribbons comprises the metal in a first atomic plane between second and third atomic planes of the chalcogen.

8. The apparatus of claim 1, wherein:
the metal is a first metal;
the gate stack comprises the insulator material in first and second layers, the first layers under the nanoribbons and the second layers over the nanoribbons; and
a portion of the transistor structure comprises:
a first of the nanoribbons comprising a first crystalline structure having the first metal in a first atomic plane between second and third first atomic planes of the chalcogen;
a first of the first layers under the first of the nanoribbons, the insulator material in the first of the first layers comprising a second crystalline structure of oxygen and a second metal different than the first metal;
a first of the second layers over the first of the nanoribbons, the insulator material in the first of the second layers comprising the second crystalline structure of oxygen and the second metal; and
the electrode material under the first of the first layers and over the first of the second layers, the electrode material comprising a third metal in a third crystalline structure.

9. The apparatus of claim 8, wherein:
the first metal is tungsten or molybdenum;
the chalcogen is sulfur or selenium;
the second metal is aluminum or hafnium; and
the third metal is titanium, the electrode material further comprising nitrogen in the third crystalline structure.

10. An apparatus, comprising:
a first terminal and a second terminal in a transistor structure in a substrate;
a gate stack in the transistor structure and between the first and second terminals, the gate stack comprising an electrode material and a gate dielectric;
a stack of channel material layers extending through the gate stack between the first and second terminals, wherein the channel material layers comprise a metal and a chalcogen, the gate dielectric is in first and second layers between the channel material layers and the electrode material, the first layers are under corresponding ones of the channel material layers, and the second layers are over the corresponding ones of the channel material layers; and
a plurality of interface layers between the first layers and the corresponding ones of the channel material layers, the interface layers comprising phosphorus.

11. The apparatus of claim 10, wherein the interface layers are monolayers of phosphorus on the first layers, the channel material layers are on the interface layers, and the second layers are on the channel material layers.

12. The apparatus of claim 11, wherein the metal is tungsten or molybdenum, and the chalcogen is sulfur or selenium.

13. The apparatus of claim 12, wherein the electrode material comprises titanium and nitrogen.

14. The apparatus of claim 13, wherein the substrate is coupled to a host component, and the transistor structure is coupled to a power supply through the host component.

15. A method, comprising:
depositing a template layer over a substrate;
depositing a first metal on the template layer;
patterning a mask layer over the template layer, wherein portions of the template layer are exposed in openings of the mask layer;
forming a first dielectric layer on the first metal, the first dielectric layer comprising a second metal in a first composition;
forming a channel material layer on the first dielectric layer, the channel material layer comprising a chalcogen and a third metal; and
forming a second dielectric layer on the channel material layer, the second dielectric layer having the first composition.

16. The method of claim 15, further comprising treating the first dielectric layer with a reactant comprising an element not present in the first composition.

17. The method of claim 16, wherein the treating the first dielectric layer with the reactant forms an interface layer on the first dielectric layer, the interface layer comprising the element.

18. The method of claim 17, wherein the element is phosphorus, and the interface layer is a monolayer of phosphorus between the channel material layer and the second metal in the first dielectric layer.

19. The method of claim 15, wherein:
the depositing the first metal comprises epitaxially depositing titanium with nitrogen in a first crystalline structure;
the forming the first dielectric layer comprises epitaxially depositing oxygen and aluminum or hafnium in a second crystalline structure;
the forming the channel material layer comprises epitaxially depositing sulfur or selenium with tungsten or molybdenum in a third crystalline structure; and
the forming the second dielectric layer comprises epitaxially depositing oxygen and aluminum or hafnium in the second crystalline structure.

20. The method of claim 15, further comprising:
removing the first metal, the second metal, the third metal, or the chalcogen from over the mask layer; and
removing the mask layer from over the substrate.
